(19) United States
(12) Patent Application Publication
(10) Pub. No.: US 2025/0176211 A1
(43) Pub. Date: May 29, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Kohei ADACHI, Tokyo (JP)

(73) Assignee: Mitsubishi Electric Corporation, Tokyo (JP)

(21) Appl. No.: 18/809,258

(22) Filed: Aug. 19, 2024

(30) Foreign Application Priority Data
Nov. 24, 2023 (JP) 2023-199167

(51) Int. Cl. H01L 29/78; H01L 21/04; H01L 29/16; H01L 29/423; H01L 29/66

(52) U.S. Cl. CPC H10D 30/668; H01L 21/0475; H10D 12/031; H10D 30/0297; H10D 62/8325; H10D 64/513

(57) ABSTRACT

A semiconductor device includes a gate lifting portion being a region in which a portion of gate wiring is lifted from a trench onto an upper surface of a semiconductor substrate. A side wall of the trench in the gate lifting portion includes: a vertical portion being perpendicular to the upper surface of the semiconductor substrate; a horizontal portion being parallel to the upper surface of the semiconductor substrate; and a sloped portion provided between the vertical portion and the horizontal portion. The sloped portion has been sloped so that the trench is widened upward, and is straight in cross section. In cross section, a corner of the vertical portion and the sloped portion does not protrude inward of the trench from a region between a tangent to the vertical portion and a tangent to the sloped portion.

### BACKGROUND OF THE INVENTION

### Field of the Invention

The present disclosure relates to semiconductor devices and methods of manufacturing the semiconductor devices.

### Description of the Background Art

A semiconductor device including a trench gate semiconductor element includes a “gate lifting portion” being a region for lifting a portion of gate wiring embedded in a trench onto a substrate to electrically connect the gate wiring and a gate pad. In the gate lifting portion, an upper end portion of the trench, that is, a corner of a front surface of the substrate and a side surface of the trench preferably has a gentle shape to prevent an electrical breakdown of a gate insulating film. The upper end portion of the trench is hereinafter referred to as a “shoulder portion of the trench”.

For example, Japanese Patent Application Laid-Open No. 2022-164865 discloses technology of rounding a shoulder portion of a trench in which gate wiring of a trench gate MOSFET has been embedded to suppress reduction in gate breakdown voltage and an increase in channel resistance. Japanese Patent Application Laid-Open No. 2016-048747 discloses technology of sloping only a shoulder portion of a trench by combining a plurality of etching processes.

In the technology disclosed in Japanese Patent Application Laid-Open No. 2022-164865, a thermal process is used to round the shoulder portion of the trench. This leads to a problem in that takt time for manufacture of a semiconductor device increases and a problem in that, due to diffusion and rearrangement of atoms in a side wall of the trench, a type of a channel region changes to an n type or an i type to cause a current leakage in a channel portion. In particular, when an impurity layer is formed on the side wall of the trench, a problem in that impurities having been implanted into the side wall of the trench are non-uniformly lost and a problem in that local enhanced oxidation occurs in a portion of the side wall of the trench into which impurities have been implanted so that a uniform slope of the side wall of the trench cannot be obtained arise, and the semiconductor device is likely to have unstable characteristics.

On the other hand, in the technology disclosed in Japanese Patent Application Laid-Open No. 2016-048747, a shape of only the shoulder portion of the trench is processed, so that characteristics of a semiconductor device are likely to be stabilized even when an impurity layer is formed on a side wall of the trench. When a sloped portion is formed in the shoulder portion of the trench in a dry etch process, however, a corner of the sloped portion and a vertical portion of the trench protrudes inward of the trench, and reliability of a gate insulating film is reduced at the protrusion.

The inventor of technology according to the present disclosure has identified a breakdown mode specific to a silicon carbide (SiC) semiconductor device, in particular, when the corner of the sloped portion and the vertical portion of the trench protrudes in a gate lifting portion of the SiC semiconductor device, including a breakdown of a gate oxide film due to electric field concentration on the corner upon application of a high voltage to a gate of a semiconductor element when a voltage is generated between a semiconductor substrate and gate wiring and a breakdown of a gate oxide film due to electric field concentration on the corner upon application of a voltage across a drain and a source while a negative bias is applied to a gate to spread a depletion layer.

### SUMMARY

It is an object of the present disclosure to prevent electric field concentration on a shoulder portion of a trench in a gate lifting portion of a trench gate silicon carbide semiconductor device.

A semiconductor device according to the present disclosure includes: a semiconductor substrate of silicon carbide; a trench formed in an upper surface of the semiconductor substrate; a gate insulating film formed on an inner surface of the trench; gate wiring formed on the gate insulating film and embedded in the trench; and a gate lifting portion being a region in which a portion of the gate wiring is lifted from the trench onto the upper surface of the semiconductor substrate. A side wall of the trench in the gate lifting portion includes: a vertical portion being perpendicular to the upper surface of the semiconductor substrate; a horizontal portion located at a top of the trench and being parallel to the upper surface of the semiconductor substrate; and a sloped portion located in a shoulder portion of the trench and provided between the vertical portion and the horizontal portion. The sloped portion has been sloped so that the trench is widened upward, and is straight in cross section. In cross section, a corner of the vertical portion and the sloped portion does not protrude inward of the trench from a region between a tangent to the vertical portion and a tangent to the sloped portion.

According to the present disclosure, electric field concentration on the shoulder portion of the trench in the gate lifting portion is suppressed to prevent a breakdown of a gate oxide film and improve reliability of the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a semiconductor device according to Embodiment 1;

FIG. 2 is a partial cross-sectional view of the semiconductor device according to Embodiment 1;

FIG. 3 is an enlarged view of a shoulder portion of a trench of the semiconductor device according to Embodiment 1;

FIG. 4 is a diagram illustrating a step of manufacturing the semiconductor device according to Embodiment 1;

FIG. 5 is a diagram illustrating a step of manufacturing the semiconductor device according to Embodiment 1;

FIG. 6 is a diagram illustrating a step of manufacturing the semiconductor device according to Embodiment 1;

FIG. 7 is a diagram illustrating a step of manufacturing the semiconductor device according to Embodiment 1;

FIG. 8 is a diagram illustrating a step of manufacturing the semiconductor device according to Embodiment 1;

FIG. 9 is a diagram illustrating a step of manufacturing the semiconductor device according to Embodiment 1;

FIG. 10 is a diagram illustrating a step of manufacturing the semiconductor device according to Embodiment 1;

FIG. 11 is a diagram illustrating a step of manufacturing the semiconductor device according to Embodiment 1;

FIG. 12 is a diagram illustrating a step of manufacturing the semiconductor device according to Embodiment 1;

FIG. 13 is a diagram illustrating a step of manufacturing the semiconductor device according to Embodiment 1;

FIG. 14 is a diagram illustrating a step of manufacturing the semiconductor device according to Embodiment 1; and

FIG. 15 is a diagram showing a relationship among the amount of wet etching in a step of reducing a hard mask, the amount of dry etching in a first etching step, and a shape of a shoulder portion of a trench.

### DESCRIPTION OF THE PREFERRED EMBODIMENTS

While description will be made in an embodiment below based on the assumption that a first conductivity type is an N type and a second conductivity type is a P type, the first conductivity type may be the P type, and the second conductivity type may be the N type. Assume that an impurity concentration in each region is defined by a peak concentration. That is to say, a region having a high (or low) impurity concentration refers to a region having a high (or low) peak impurity concentration.

### Embodiment 1

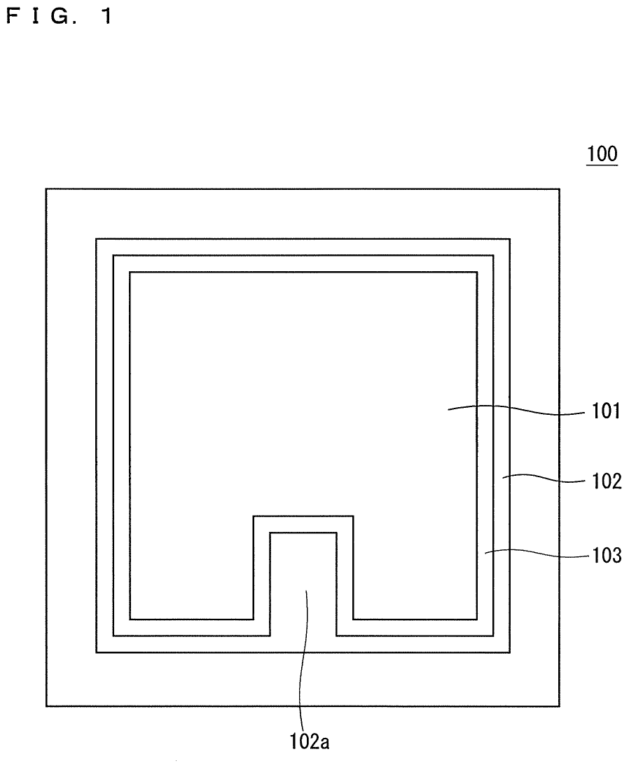

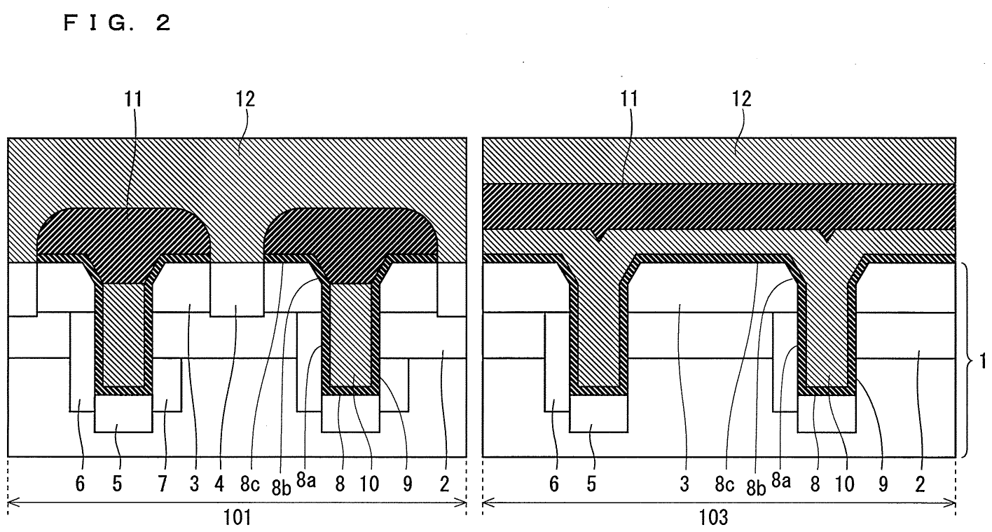

FIG. 1 is a plan view illustrating a configuration of a semiconductor device 100 according to Embodiment 1. FIG. 2 is a partial cross-sectional view of the semiconductor device 100. Description will herein be made based on the assumption that a semiconductor element of the semiconductor device 100 is a metal oxide semiconductor field effect transistor (MOSFET). The semiconductor element, however, may be any semiconductor element, such as an insulated gate bipolar transistor (IGBT) and a reverse conducting IGBT (RC-IGBT), as long as it is a trench gate semiconductor element.

As illustrated in FIG. 1, the semiconductor device 100 includes a cell portion 101, a gate routing portion 102, and a gate lifting portion 103.

The cell portion 101 is a region in which a cell of the semiconductor element (MOSFET) is formed.

The gate routing portion 102 is a region in which gate routing wiring of, for example, aluminum for connecting a gate pad and gate wiring of the semiconductor element is disposed. The gate routing portion 102 thus includes a gate pad region 102a in which the gate pad is disposed.

The gate lifting portion 103 is a region for lifting a portion of the gate wiring of the semiconductor element onto a semiconductor substrate to connect the gate wiring to the gate routing wiring. The gate lifting portion 103 is thus provided at a boundary between the cell portion 101 and the gate routing portion 102.

FIG. 2 is a cross-sectional view of the cell portion 101 and the gate lifting portion 103 of the semiconductor device 100 according to Embodiment 1.

The semiconductor device 100 is formed using an N type semiconductor substrate 1 of a silicon carbide semiconductor. In the cell portion 101, a P type channel doped layer 2 is formed in a surface layer of the semiconductor substrate 1. In a surface layer of the channel doped layer 2, an N type source layer 3 and a P type contact layer 4 having a higher impurity concentration than the channel doped layer 2 are selectively formed.

Trenches 8 are formed in an upper surface of the semiconductor substrate 1 to penetrate the source layer 3 and the channel doped layer 2. A gate insulating film 9 formed, for example, of a silicon oxide film is formed on an inner surface of each of the trenches 8. Gate wiring 10 of, for example, polysilicon is formed on the gate insulating film 9 to be embedded in the trench 8. The semiconductor substrate 1, the channel doped layer 2, the source layer 3, the gate insulating film 9, and the gate wiring 10 constitute a basic structure of the MOSFET. An N type region below the source layer 3 of the semiconductor substrate 1 serves as a so-called drift layer, and the trench 8 extends into the drift layer.

In the present embodiment, a P type field relaxation layer 5 formed at a bottom of the trench 8 and a trench side wall P type layer 6 and a trench side wall N type layer 7 formed on a side wall of the trench 8 are provided in addition to the above-mentioned basic structure. The field relaxation layer 5 relaxes an electric field generated at the bottom of the trench 8. The trench side wall P type layer 6 connects the field relaxation layer 5 and the channel doped layer 2 to apply a source potential to the field relaxation layer 5. The trench side wall N type layer 7 prevents the field relaxation layer 5 from narrowing a current path between the trenches 8 to contribute to reduction in on resistance of the MOSFET.

An interlayer insulating film 11 is formed over the semiconductor substrate 1 to cover the gate wiring 10. A metal electrode 12 as a source electrode is formed on the interlayer insulating film 11. The metal electrode 12 is electrically connected to the source layer 3 and the contact layer 4 through contact holes formed in the interlayer insulating film 11. Although not illustrated, a drain electrode of the MOSFET is provided on a lower surface of the semiconductor substrate 1.

In the gate lifting portion 103, the gate insulating film 9 and the gate wiring 10 extend from the interior of the trenches 8 across the upper surface of the semiconductor substrate 1 to lift the gate wiring 10 onto the semiconductor substrate 1.

In the gate lifting portion 103, the gate insulating film 9 and the gate wiring 10 are provided to span the trenches 8, and the interlayer insulating film 11 is formed to cover the gate wiring 10 extending across the upper surface of the semiconductor substrate 1, so that the interlayer insulating film 11 does not have any contact holes to connect the metal electrode 12 to the source layer 3. Thus, in the gate lifting portion 103, the contact layer 4 is not required to be provided. The trench side wall N type layer 7 is also not required to be provided as the gate lifting portion 103 is not to be the current path. A portion of the source layer 3 at least adjacent to a sloped portion 8b of each of the trenches 8 in the gate lifting portion 103, however, may be changed to a P type semiconductor layer similar to the contact layer 4 to suppress a leakage current generated in the gate lifting portion 103, which will be described below.

A shape of each of the trenches 8 will be described herein. As illustrated in FIG. 2, a side wall of the trench 8 includes a vertical portion 8a being perpendicular to the upper surface of the semiconductor substrate 1, a horizontal portion 8c located at a top of the trench 8 and being parallel to the upper surface of the semiconductor substrate 1, and a sloped portion 8b located in a shoulder portion of the trench 8 and provided between the vertical portion 8a and the horizontal portion 8c. The sloped portion 8b has been sloped so that the trench 8 is widened upward. The sloped portion 8b is not round and is straight in cross section. “Perpendicular”, “parallel”, and “straight” herein do not intend strictly perpendicular, parallel, and straight and are only required to be substantially perpendicular, parallel, and straight.

The gate insulating film 9 formed on the side wall of the trench 8 is formed uniformly across the vertical portion 8a, the sloped portion 8b, and the horizontal portion 8c. In the cell portion 101, the gate wiring 10 is fit below a corner of the sloped portion 8b and the vertical portion 8a of the trench 8. In the gate lifting portion 103, the gate wiring 10 is formed to cover the vertical portion 8a, the sloped portion 8b, and the horizontal portion 8c of the trench 8.

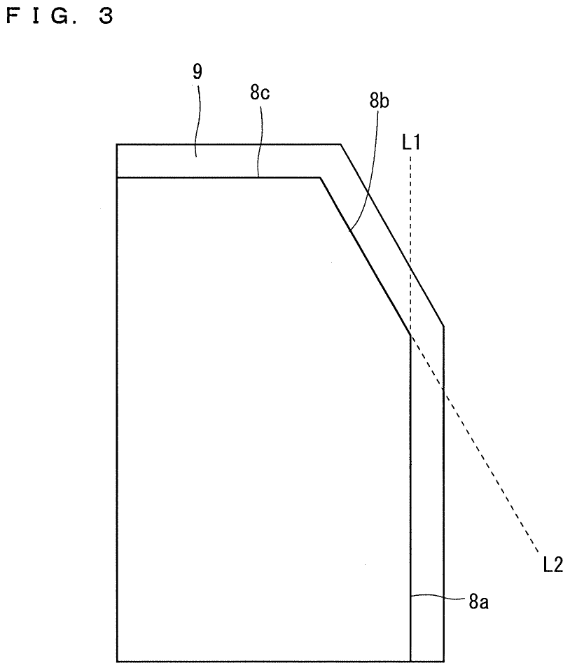

FIG. 3 is an enlarged view of the shoulder portion of the trench 8. The gate wiring 10 is not illustrated in FIG. 3. As illustrated in FIG. 3, in cross section, the corner of the vertical portion 8a and the sloped portion 8b of the trench 8 does not protrude inward of the trench 8 from a region between a tangent L1 to the vertical portion 8a and a tangent L2 to the sloped portion 8b. That is to say, the corner of the vertical portion 8a and the sloped portion 8b of the trench 8 does not protrude inward of the trench 8 from the tangent L1 to the vertical portion 8a and does not protrude upward from the tangent L2 to the sloped portion 8b.

In particular, in the gate lifting portion 103, the shoulder portion of the trench 8 is covered with the gate wiring 10, so that, if the corner of the vertical portion 8a and the sloped portion 8b of the trench 8 protrudes, electric field concentration is likely to occur at the protrusion. When the corner of the vertical portion 8a and the sloped portion 8b of the trench 8 does not protrude inward of the trench 8 from the region between the tangent L1 to the vertical portion 8a and the tangent L2 to the sloped portion 8b of the trench 8 as in the present embodiment, electric field concentration on the shoulder portion of the trench 8 covered with the gate wiring 10 is suppressed. As a result, a breakdown of the gate insulating film 9 can be prevented to improve reliability of the semiconductor device.

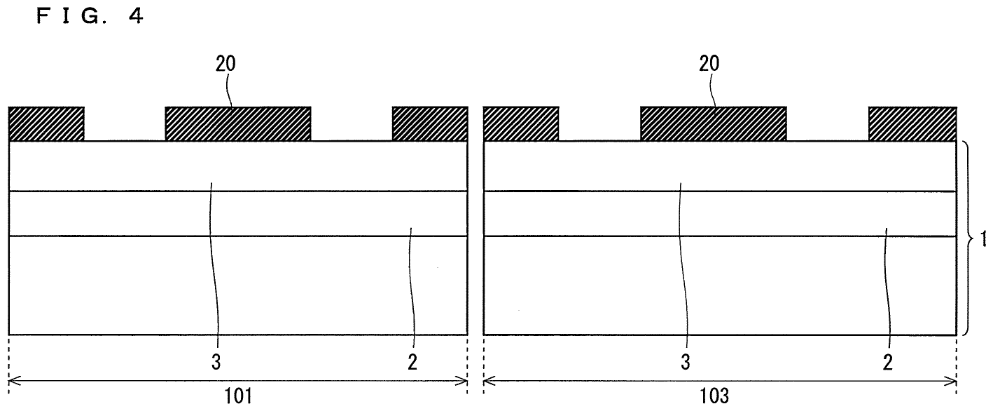

A method of manufacturing the semiconductor device 100 according to Embodiment 1 will be described with reference to step diagrams of FIGS. 4 to 14.

First, the semiconductor substrate 1 of N type silicon carbide is prepared. The semiconductor substrate 1 is formed by forming an epitaxial layer of silicon carbide on a substrate of silicon carbide.

Next, impurities are ion implanted into the surface layer (epitaxial layer) of the semiconductor substrate 1 to form the P type channel doped layer 2 and the N type source layer 3. As impurities for forming the P type semiconductor layer, Al (aluminum) is used, for example. As impurities for forming an N type semiconductor layer, N (nitrogen) is used, for example.

Next, an oxide film is deposited on the semiconductor substrate 1, a resist having openings in a pattern of the trenches 8 is formed on the oxide film, and the oxide film is etched with the resist as a mask. A hard mask 20 formed of the oxide film having openings in regions in which the trenches 8 are formed is thereby formed on the semiconductor substrate 1 as illustrated in FIG. 4.

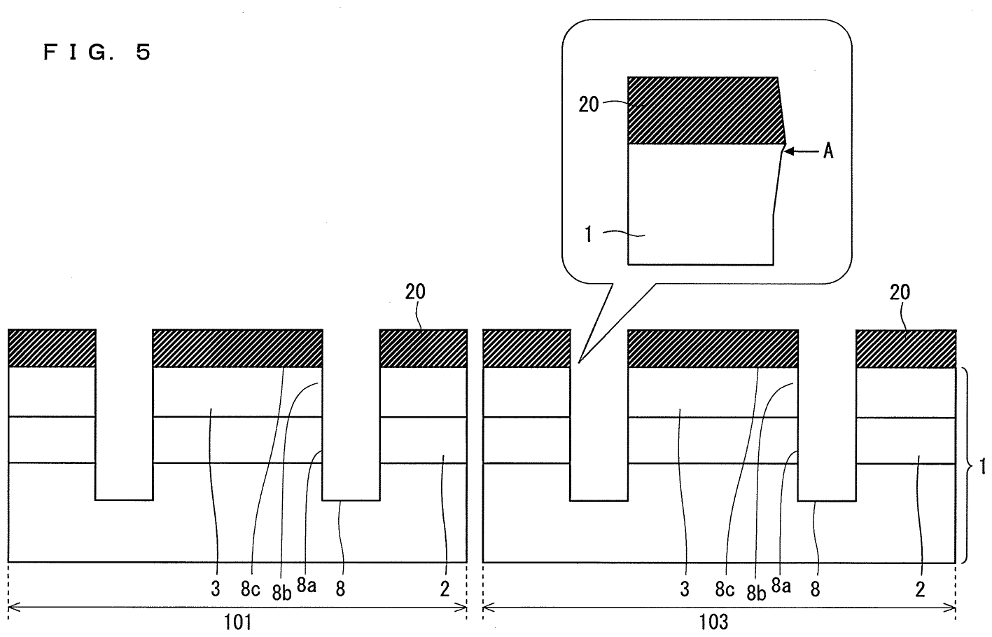

Next, the semiconductor substrate 1 is etched with the hard mask 20 as a mask to form the trenches 8 as illustrated in FIG. 5. The vertical portion 8a of each of the trenches 8 is formed by etching, but, in this case, the shoulder portion (an upper end portion of the vertical portion 8a) of the trench 8 has an overhanging protrusion A at an interface with the hard mask 20.

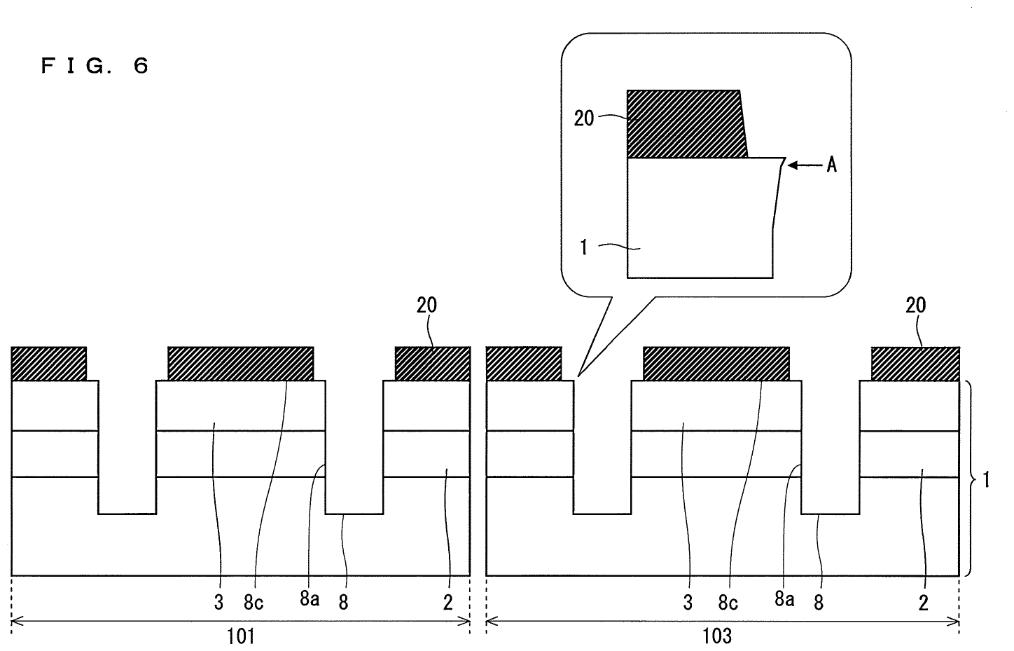

The hard mask 20 is then wet etched, for example, to reduce a size of the hard mask 20 by a given dimension to expose the shoulder portion of the trench 8 from the hard mask 20 as illustrated in FIG. 6.

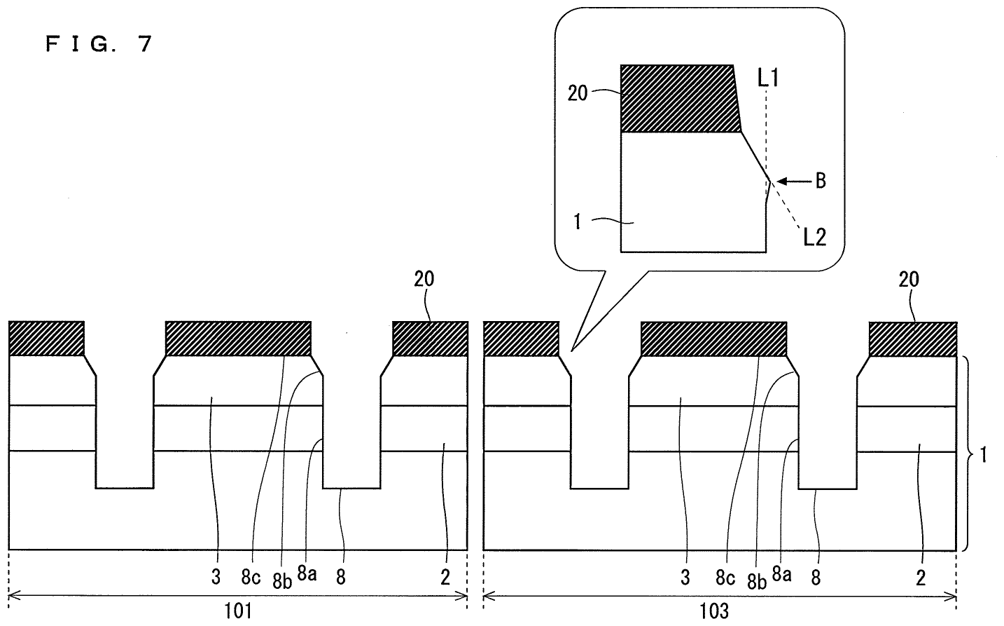

The shoulder portion of the trench 8 is then subjected to anisotropic dry etching, such as reactive ion etching, with the reduced hard mask 20 as a mask. As a result, the sloped portion 8b is formed in the shoulder portion of the trench 8 as illustrated in FIG. 7. This step is hereinafter referred to as a “first etching step”.

Anisotropic etching is performed in the first etching step to selectively process the shoulder portion of the trench 8. Specifically, when etching using an etchant, such as Freon, having a larger molecular diameter and a shorter mean free path (than those in hydrogen treatment) is applied to the first etching step, an etch rate near the shoulder portion of the trench 8 can suitably be increased. In addition, a high etch rate in the shoulder portion of the trench 8 due to progress of reaction from both an upper surface and a side surface and a low etch rate at the bottom of the trench 8 due to surface reaction contribute to selective etching in the shoulder portion of the trench 8. These effects suppress a change in shape of the bottom of the trench 8 in the first etching step to contribute to improvement in reliability of the semiconductor device 100.

When the sloped portion 8b is formed in the first etching step, at least top of the protrusion A is removed. When the protrusion A has a large height, however, a protrusion B as a remaining portion of the protrusion A might protrude inward of the trench 8 from the region between the tangent L1 to the vertical portion 8a and the tangent L2 to the sloped portion 8b even after the first etching step as illustrated in FIG. 7.

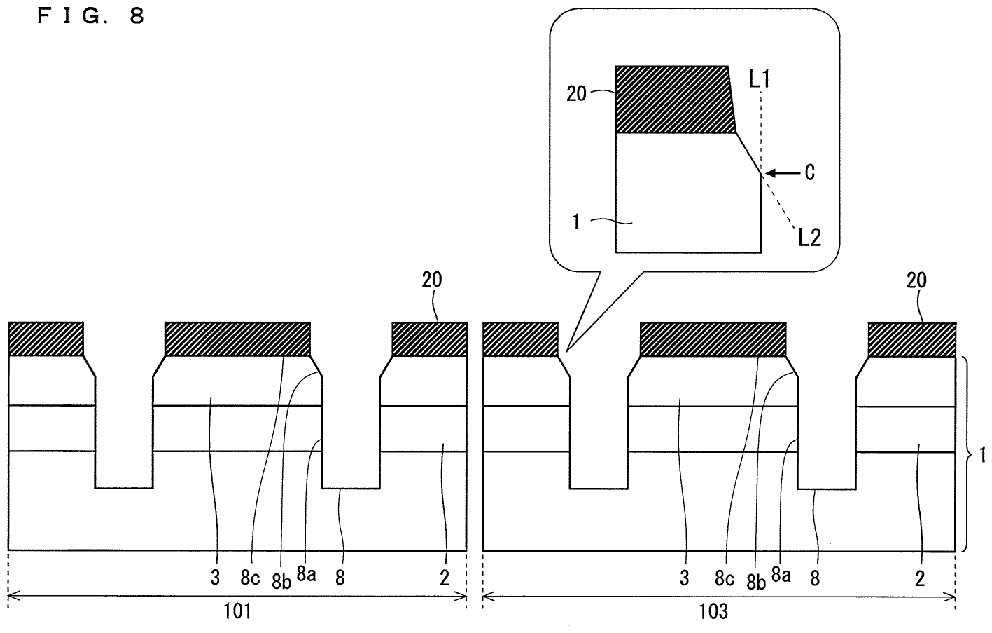

Isotropic dry etching using the hard mask 20 as a mask is thus performed after the first etching step to remove the protrusion B. This causes the corner of the vertical portion 8a and the sloped portion 8b to be an inflection point C within the region between the tangent L1 to the vertical portion 8a and the tangent L2 to the sloped portion 8b as illustrated in FIG. 8. This step is hereinafter referred to as a “second etching step”.

As described above, the first etching step of forming the sloped portion 8b in the shoulder portion of the trench 8 and the second etching step are self-alignment processes using the hard mask 20 used in the trench formation step as a mask. The sloped portion 8b can thus be formed with a high positional accuracy without adding a photoengraving step.

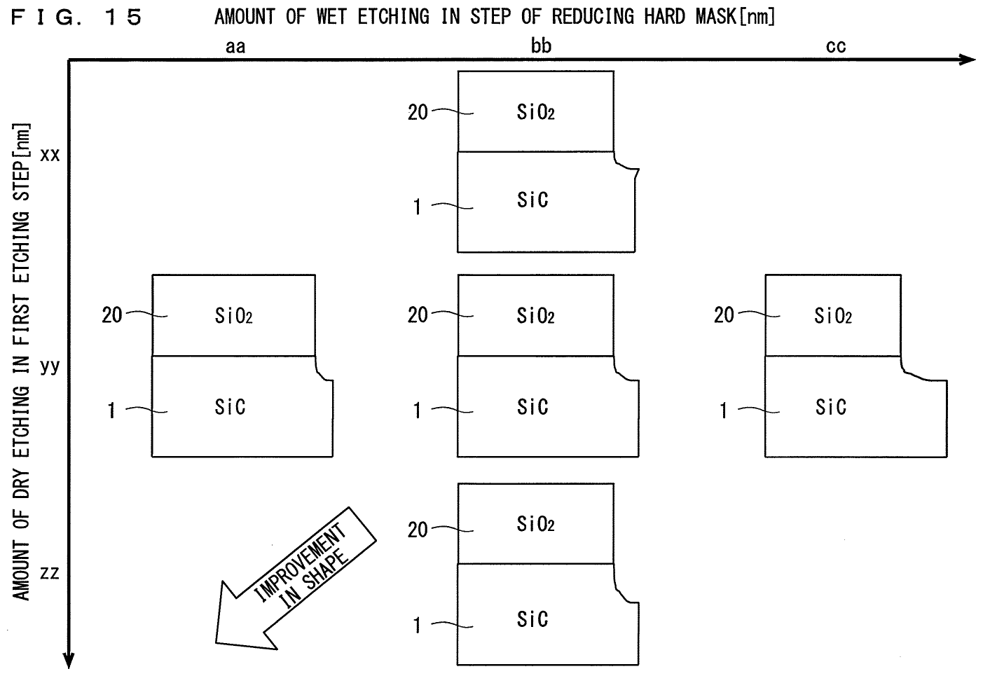

FIG. 15 shows a relationship among the amount of wet etching in the step of reducing the hard mask 20, the amount of dry etching in the first etching step, and a shape of the shoulder portion of the trench 8. As shown in FIG. 15, when the amount of etching in the step of reducing the hard mask 20 is reduced, and the amount of etching in the first etching step is increased, the shape of the shoulder portion of the trench 8 is improved (the protrusion A is reduced in size). It is preferable to reduce the amount of etching in the step of reducing the hard mask 20 compared with the amount of etching in the first etching step. This enables reduction in size of the protrusion B remaining after the first etching step and easy removal of the protrusion B in the second etching step.

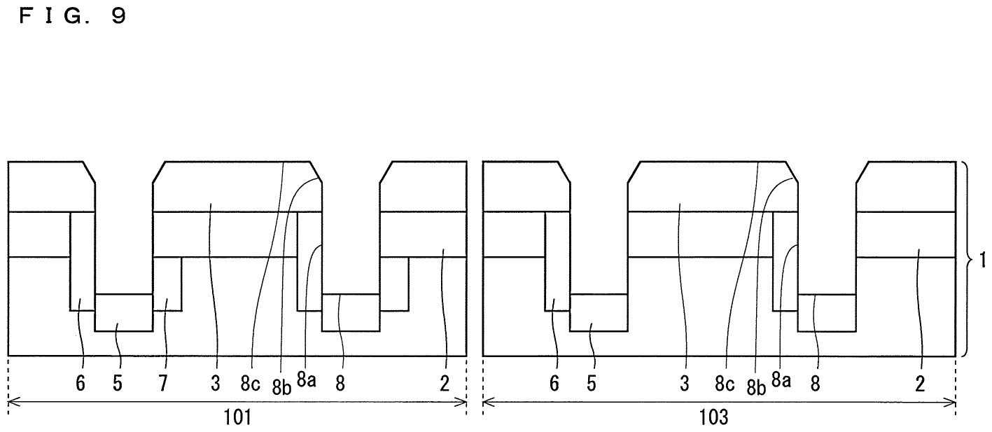

After the second etching step, the hard mask 20 is removed. The field relaxation layer 5, the trench side wall P type layer 6, and the trench side wall N type layer 7 are then formed by selective ion implantation as illustrated in FIG. 9. The field relaxation layer 5 may be formed between the step of forming the trenches 8 (FIG. 5) and the step of reducing the hard mask 20 (FIG. 6). In this case, the field relaxation layer 5 can be formed by vertical ion implantation using the hard mask 20 before being reduced as a mask, and implantation of impurities into the side wall of the trench 8 when the field relaxation layer 5 is formed can be suppressed to improve reliability of the semiconductor device 100.

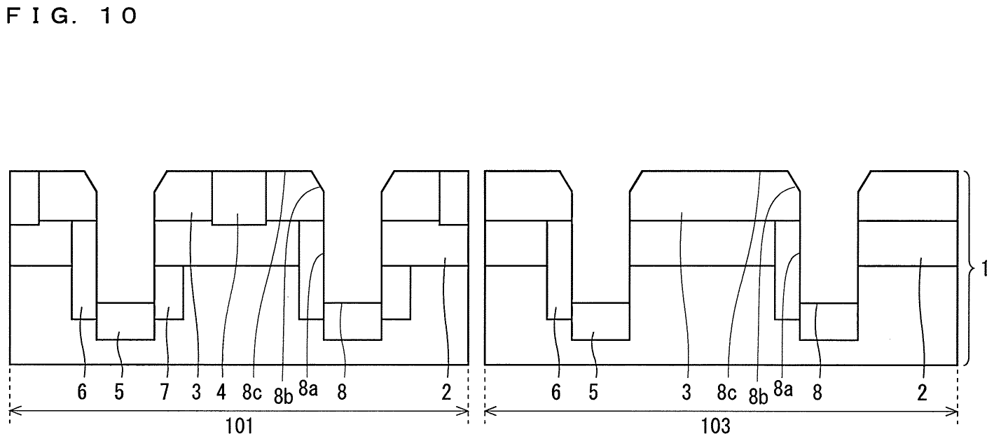

Furthermore, the P type contact layer 4 is formed by selective ion implantation as illustrated in FIG. 10. In this case, P type impurities may be implanted also in the gate lifting portion 103 to change a portion of the N type source layer 3 at least adjacent to the vertical portion 8a of the trench 8 in the gate lifting portion 103 to a P type semiconductor layer. This is because the source layer 3 in the gate lifting portion 103 is surrounded by the gate wiring 10 and thus can cause an increase in leakage current. The leakage current increases in an N type semiconductor presumably because an excessive number of electrons with high mobility is likely to cause the increase in leakage current.

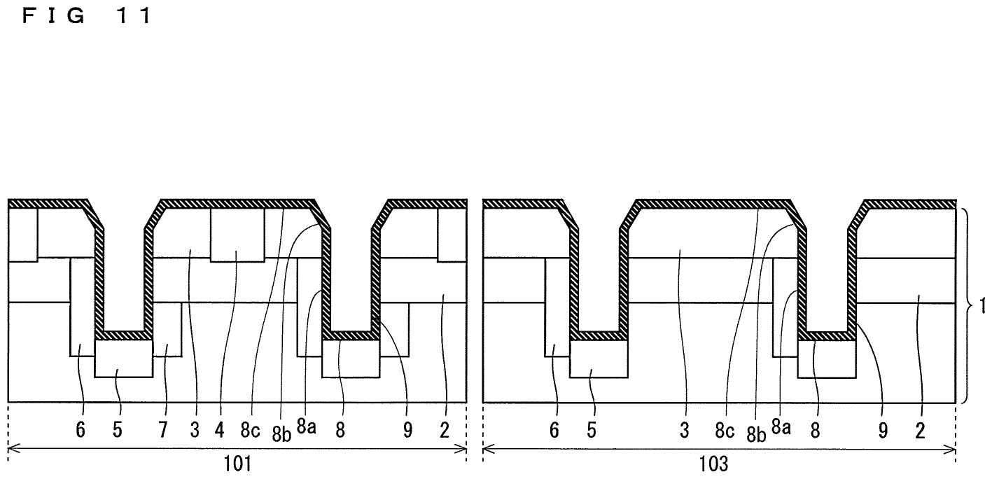

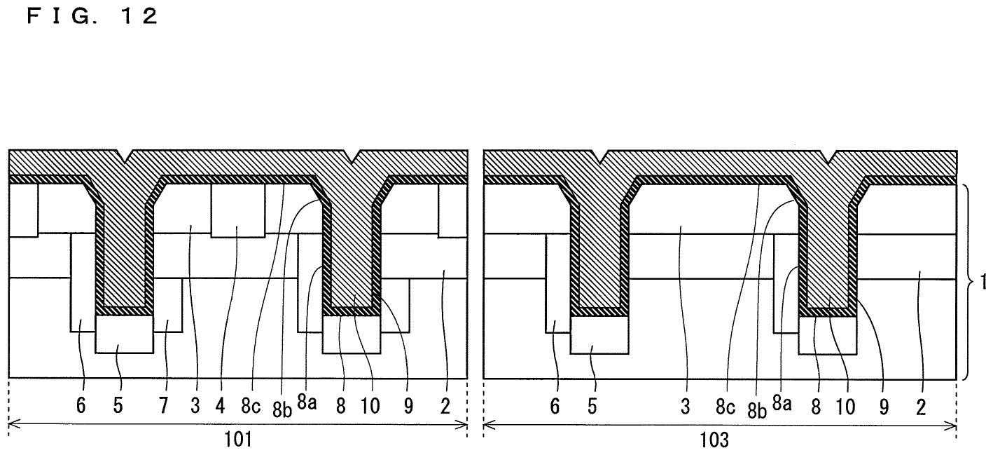

After all the steps of implanting impurities are performed, heat treatment for activating the implanted impurities is performed. Then, as illustrated in FIG. 11, the gate insulating film 9 is formed on the upper surface of the semiconductor substrate 1 including the interior of each of the trenches 8. Furthermore, as illustrated in FIG. 12, a conductive film of, for example, polysilicon is deposited on the gate insulating film 9 to form the gate wiring 10.

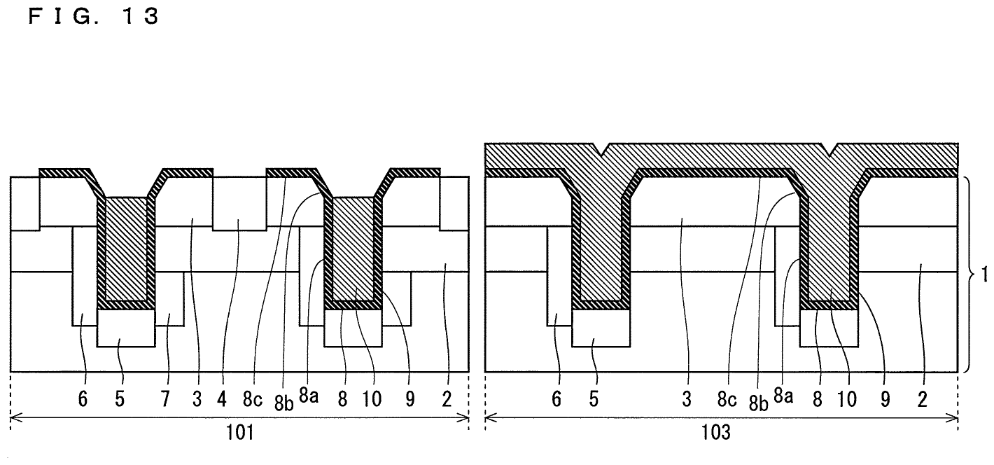

As illustrated in FIG. 13, the gate wiring 10 is patterned by selective etching. In this step of patterning the gate wiring 10, the gate wiring 10 in the cell portion 101 is etched back to remove the gate wiring 10 from the upper surface of the semiconductor substrate 1 in the cell portion 101 while leaving the gate wiring 10 within the trench 8 in the cell portion 101. In this case, etching is performed until an upper surface of the gate wiring 10 remaining within the trench 8 is fit below the inflection point C in the shoulder portion of the trench 8.

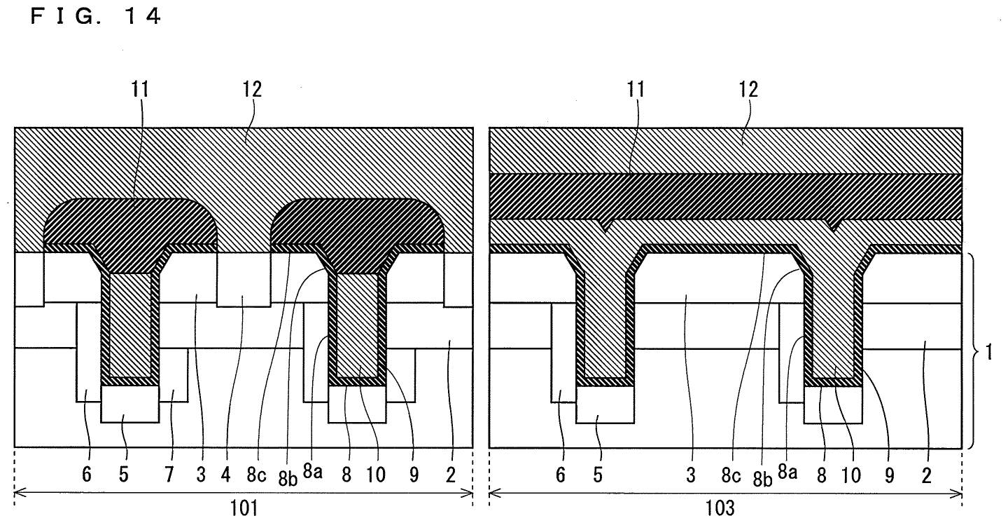

The interlayer insulating film 11 is formed on the semiconductor substrate 1. After the contact holes are formed in the interlayer insulating film 11, as illustrated in FIG. 14, the metal electrode 12 and the gate pad (not illustrated) are formed on the interlayer insulating film 11, and a protective film, such as a passivation film, is formed on the metal electrode 12 and the gate pad as necessary and is opened to expose a portion of the metal electrode 12 and the gate pad.

After the semiconductor substrate 1 is thinned by grinding of a rear surface of the semiconductor substrate 1, the drain electrode of metal is formed on the rear surface of the semiconductor substrate 1 to complete the semiconductor device 100.

A dicing step of singulating the semiconductor device 100 and a step of testing the semiconductor device 100 are then performed. The semiconductor device 100 is subjected to modularizing and the like to eventually form an inverter circuit and the like.

The above-mentioned embodiment can be modified and omitted as appropriate.

### APPENDICES

Various aspects of the present disclosure will collectively be described below as appendices.

### APPENDIX 1

A semiconductor device comprising:
a semiconductor substrate of silicon carbide;
a trench formed in an upper surface of the semiconductor substrate;
a gate insulating film formed on an inner surface of the trench;
gate wiring formed on the gate insulating film and embedded in the trench; and
a gate lifting portion being a region in which a portion of the gate wiring is lifted from the trench onto the upper surface of the semiconductor substrate, wherein
a side wall of the trench in the gate lifting portion includes:
   a vertical portion being perpendicular to the upper surface of the semiconductor substrate;
   a horizontal portion located at a top of the trench and being parallel to the upper surface of the semiconductor substrate; and
   a sloped portion located in a shoulder portion of the trench and provided between the vertical portion and the horizontal portion,
the sloped portion has been sloped so that the trench is widened upward, and is straight in cross section, and
in cross section, a corner of the vertical portion and the sloped portion does not protrude inward of the trench from a region between a tangent to the vertical portion and a tangent to the sloped portion.

### APPENDIX 2

The semiconductor device according to Appendix 1, wherein
the trench extends into a drift layer of a first conductivity type, and
a field relaxation layer of a second conductivity type is formed at a bottom of the trench.

### APPENDIX 3

The semiconductor device according to Appendix 2, wherein
an impurity layer of the second conductivity type connected to the field relaxation layer is formed on a portion of the side wall of the trench.

### APPENDIX 4

The semiconductor device according any one of Appendices 1 to 3, wherein
in the gate lifting portion, a portion of the semiconductor substrate at least adjacent to the vertical portion of the trench is a P type semiconductor layer.

### APPENDIX 5

A method of manufacturing a semiconductor device, the method comprising:
a step of forming a mask on an upper surface of a semiconductor substrate;
a step of forming a trench including a vertical portion perpendicular to the upper surface of the semiconductor substrate by etching using the mask;
a step of reducing the mask;
a first etching step of forming a sloped portion in a shoulder portion of the trench by etching using the reduced mask; and
a second etching step of etching, after the first etching step, a corner of the vertical portion and the sloped portion by etching using the reduced mask.

### APPENDIX 6

The method of manufacturing the semiconductor device according to Appendix 5, wherein
etching in the first etching step is anisotropic etching, and
etching in the second etching step is isotropic etching.

### APPENDIX 7

The method of manufacturing the semiconductor device according to Appendix 5 or 6, wherein
the amount of etching in the step of reducing the mask is smaller than the amount of etching in the first etching step.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor substrate of silicon carbide;
a trench formed in an upper surface of the semiconductor substrate;
a gate insulating film formed on an inner surface of the trench;
gate wiring formed on the gate insulating film and embedded in the trench; and
a gate lifting portion being a region in which a portion of the gate wiring is lifted from the trench onto the upper surface of the semiconductor substrate, wherein
a side wall of the trench in the gate lifting portion includes:
a vertical portion being perpendicular to the upper surface of the semiconductor substrate;
a horizontal portion located at a top of the trench and being parallel to the upper surface of the semiconductor substrate; and
a sloped portion located in a shoulder portion of the trench and provided between the vertical portion and the horizontal portion,
the sloped portion has been sloped so that the trench is widened upward, and is straight in cross section, and
in cross section, a corner of the vertical portion and the sloped portion does not protrude inward of the trench from a region between a tangent to the vertical portion and a tangent to the sloped portion.

2. The semiconductor device according to claim 1, wherein
the trench extends into a drift layer of a first conductivity type, and
a field relaxation layer of a second conductivity type is formed at a bottom of the trench.

3. The semiconductor device according to claim 2, wherein
an impurity layer of the second conductivity type connected to the field relaxation layer is formed on a portion of the side wall of the trench.

4. The semiconductor device according to claim 1, wherein
in the gate lifting portion, a portion of the semiconductor substrate at least adjacent to the vertical portion of the trench is a P type semiconductor layer.

5. The semiconductor device according to claim 2, wherein
in the gate lifting portion, a portion of the semiconductor substrate at least adjacent to the vertical portion of the trench is a P type semiconductor layer.

6. The semiconductor device according to claim 3, wherein
in the gate lifting portion, a portion of the semiconductor substrate at least adjacent to the vertical portion of the trench is a P type semiconductor layer.

7. A method of manufacturing a semiconductor device, the method comprising:
forming a mask on an upper surface of a semiconductor substrate;
forming a trench including a vertical portion perpendicular to the upper surface of the semiconductor substrate by etching using the mask;
reducing the mask;
forming a sloped portion in a shoulder portion of the trench by first etching using the reduced mask; and
etching, after the first etching, a corner of the vertical portion and the sloped portion by second etching using the reduced mask.

8. The method of manufacturing the semiconductor device according to claim 7, wherein
the first etching is anisotropic etching, and
the second etching is isotropic etching.

9. The method of manufacturing the semiconductor device according to claim 7, wherein
the amount of etching in reducing the mask is smaller than the amount of etching in the first etching.

10. The method of manufacturing the semiconductor device according to claim 8, wherein
the amount of etching in reducing the mask is smaller than the amount of etching in the first etching.
